(19) United States
(12) Patent Application Publication
(10) Pub. No.: US 2015/0348893 A1
(43) Pub. Date: Dec. 3, 2015

(54) METHOD OF MANUFACTURING THREE-DIMENSIONAL INTEGRATED CIRCUIT COMPRISING ALUMINUM NITRIDE INTERPOSER

(71) Applicant: NATIONAL CHUNG SHAN INSTITUTE OF SCIENCE AND TECHNOLOGY, LONGTAN TOWNSHIP (TW)

(72) Inventors: CHIH WANG, LONGTAN (TW); CHI-HAW CHIANG, LONGTAN (TW); YU-PING WANG, LONGTAN (TW); YANG-KUO KUO, LONGTAN TOWNSHIP (TW)

(73) Assignee: NATIONAL CHUNG SHAN INSTITUTE OF SCIENCE AND TECHNOLOGY, LONGTAN TOWNSHIP (TW)

(21) Appl. No.: 14/289,937

(22) Filed: May 29, 2014

(51) Int. Cl. H01L 23/498; H01L 21/48; H01L 23/00

(52) U.S. Cl. CPC H01L 23/49827; H01L 24/81; H01L 24/17; H01L 23/49811; H01L 23/49894; H01L 21/486; H01L 24/11; H01L 2924/05032; H01L 2224/16225; H01L 2924/2064; H01L 2924/20641; H01L 2924/1461; H01L 2924/14; H01L 2924/13091; H01L 2924/1436; H01L 2924/1421; H01L 2924/141; H01L 2924/40102; H01L 2924/40503; H01L 2924/20301; H01L 2924/20261; H01L 2224/16113; H01L 2224/13025

(57) ABSTRACT

A method of manufacturing a three-dimensional integrated circuit comprising an aluminum nitride interposer is introduced. The method includes providing a first circuit component; providing a plurality of first conductive blocks on the first circuit component; providing an aluminum nitride interposer on the first circuit component, wherein the aluminum nitride interposer has microvias each comprising therein a conductor with an end in contact with a corresponding one of the first conductive blocks; providing second conductive blocks on the aluminum nitride interposer, wherein the second conductive blocks are in contact with the other ends of the conductors in the microvias; and providing at least a second circuit component disposed on the aluminum nitride interposer and electrically connected to the first circuit component through the first and second conductive blocks and the conductors.

### FIELD OF TECHNOLOGY

The present invention relates to methods of manufacturing a three-dimensional integrated circuit, and more particularly, to a method of manufacturing a three-dimensional integrated circuit comprising an aluminum nitride interposer.

### BACKGROUND

A three-dimensional integrated circuit (3D-IC) comprises at least two integrated circuits or circuit components. They stack and electrically connect to each other in three dimensions and their interconnections between the integrated circuits or circuit components are achieved through a plurality of microvias. Hence, the three-dimensional integrated circuit comprises an interposer with a lot of microvias.

Three-dimensional integrated circuit packaging technology conventionally uses a silicon wafer as an interposer because the silicon-based semiconductor manufacturing processes are well-understood. For wafer-level heterogeneous integration, however, the compatibilities of materials between components/substrate and components/components need to be taken considerations. For example, a silicon interposer has some serious drawbacks and they need to be solved. First, there is obviously CTE (the coefficient of thermal expansion) mismatch between components and a substrate, which leads to a warpage induced by thermal stress. In addition, silicon has a poor insulation property (˜10³ Ω-cm), which may further lead to phenomena of the short current or the leakage current. Devices would cause problems of signals such as coupling, noising and loss, especially under a high power or wafer stacking conditions. Hence, the manufacturing processes of a silicon interposer require an additional process of a silicon dioxide (SiO₂) layer deposition as an insulator. However, this layer not only decreases the heat dissipation capability of a silicon interposer but also increases the cost of process.

A research team of the Georgia Institute of Technology first reported a glass as an interposer for packaging technique to solve the problems from silicon-based processes. Although a glass has a good electrical insulation property (10¹⁰˜10¹⁴ Ω-cm), its thermal conductivity only shows a low range of 0.8˜1.3 W/m-k, which reveals that it could be suitable for a low-power 3D chip stacking products. For high-power 3D-IC products, its poor heat conductivity would lead to a serious accumulation of heat, and further result in heat failure of components, deterioration of product reliability, and then reduction of the lifetimes of products. In view of this, it is important to develop a new material as an interposer for 3D-IC package in high power device applications.

### SUMMARY

In view of the aforesaid drawbacks of the prior art, it is an objective of the present invention to provide a method of manufacturing a three-dimensional integrated circuit comprising an aluminum nitride interposer to integrate a first circuit component, a conductive block, an aluminum nitride interposer, at least a second circuit component with each other, with a view to manufacturing a three-dimensional integrated circuit comprising an aluminum nitride interposer which manifests desirable features, such as quick heat dissipation, low warpage, low leakage current, and low noise.

In order to achieve the objectives, the present invention provides a method of manufacturing a three-dimensional integrated circuit comprising an aluminum nitride interposer. The method comprises the steps of: providing a first circuit component; providing a plurality of first conductive blocks on the first circuit component; providing an aluminum nitride interposer on the first circuit component, wherein the aluminum nitride interposer comprises a plurality of microvias each having therein a conductor with an end in contact with a corresponding one of the first conductive blocks; providing a plurality of second conductive blocks on the aluminum nitride interposer, wherein the second conductive blocks are in contact with other ends of the conductors in the microvias, respectively; and providing at least a second circuit component on the aluminum nitride interposer, wherein the at least a second circuit component is electrically connected to the first circuit component through the first and second conductive blocks and the conductors.

The first circuit component is provided in the form of a printed circuit board (PCB), but the present invention is not limited thereto. The at least a second circuit component is provided in the form of a CMOS, a DRAM, an ambient light sensor, a power amplifier, a RF and inertia MEMS, or a combination thereof, but the present invention is not limited thereto.

The aluminum nitride shows excellent physical and chemical properties, including a thermal conductivity coefficient of ˜200 W/mk, high chemical stability, and excellent electrical insulation of ˜10¹⁴ Ω-cm. According to the present invention, the interposer of the three-dimensional integrated circuit is made of aluminum nitride. The content of interposer is 80˜99.95% aluminum nitride with a thickness of 20-100 μm. According to the present invention, the aluminum nitride interposer has therein a plurality of microvias with a diameter of 5-100 μm.

The microvias of aluminum nitride interposer are formed by femtosecond laser pulses, such as a titanium-sapphire laser beam (in accordance with parameters, including a center wavelength of 800 nm, a pulse width <100 fs, a laser power of 200˜1,000 mW, and a frequency of 1,000˜10,000 Hz), but the present invention is not limited thereto, as it is also practicable for the present invention to form the microvias of an aluminum nitride interposer by wet etching or dry etching processes.

Both of the conductive blocks and the conductors are intended to electrically connect the first circuit component to the at least a second circuit component. The conductive blocks and the conductors in the microvias are conductor. The conductive blocks are provided in the form of tin balls, but the present invention is not limited thereto. The conductors are made of copper, tungsten, silver, tin or conductive paste, but the present invention is not limited thereto.

The above overview, the following description, and the accompanying drawings are intended to illustrate the technical solution and means for use in achieving the objectives of the present invention as well as the advantages thereof. The other objectives and advantages of the present invention are described below and illustrated with the accompanying drawings.

### BRIEF DESCRIPTION

Objectives, features, and advantages of the present invention are hereunder illustrated with specific embodiments in conjunction with the accompanying drawings, in which:

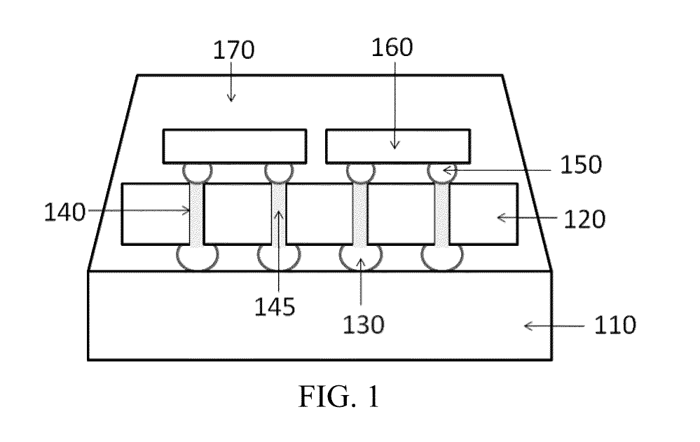

FIG. 1 is a schematic view of an 3D-IC package comprising an aluminum nitride interposer according to an embodiment of the present invention; and

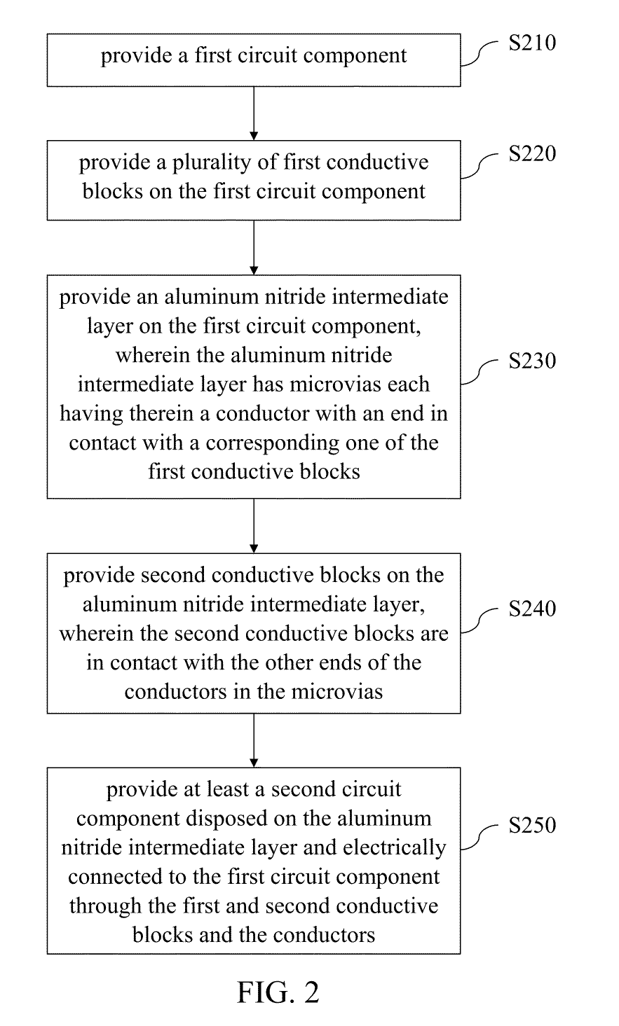

FIG. 2 is a schematic view of the process flow of a method of manufacturing a three-dimensional integrated circuit comprising an aluminum nitride interposer according to an embodiment of the present invention.

### DETAILED DESCRIPTION

The present invention provides a method of manufacturing a three-dimensional integrated circuit comprising an aluminum nitride interposer. The method essentially entails: performing drilling and copper filled via processes on an 8-inch or 12-inch aluminum nitride wafer to form an aluminum nitride interposer; and connecting chips to a printed circuit board (PCB) with tin balls by alignment and connection technologies, and its package structure is schematically depicted with FIG. 1. Aluminum nitride has excellent properties, that is, its high electrical insulation (˜10¹⁴ Ω-cm) and high thermal conductivity (˜200 W/m-k), and thus aluminum nitride is a desirable candidate for interposer to substitute for the conventional ones, such as silicon and glass. Due to its high thermal conductivity and low leakage current, aluminum nitride as an interposer is expected to enhance the performance of devices and increase the lifetime of products. Moreover, the CTE of aluminum nitride is 4.2 ppm/K and 5.3 ppm/K with different lattice constant of 3.11 Å and 4.98 Å, respectively. They make a good match with power devices, which are conventionally fabricated by GaN (its CTE is 5.59 ppm/K and 3.17 ppm/K with different lattice constant of 3.189 Å and 5.16 Å, respectively). As compared to silicon and glass (their CTE is 2.59 ppm/K and 3.0˜12 0.0 ppm/K, respectively), aluminum nitride as an interposer can efficiently reduce the thermal stress and increase the reliability during the stacking processes.

Referring to FIG. 1 and FIG. 2, there are shown in FIG. 1 a schematic view of an 3D-IC package comprising an aluminum nitride interposer according to an embodiment of the present invention, and shown in FIG. 2 a schematic view of the process flow of a method of manufacturing a three-dimensional integrated circuit comprising an aluminum nitride interposer according to an embodiment of the present invention. As shown in FIG. 1 and FIG. 2, the present invention provides a method of manufacturing a three-dimensional integrated circuit comprising an aluminum nitride interposer. The method comprises the steps of: providing a first circuit component 110 (S210), wherein the first circuit component 110 is in the number of at least one and is provided in the form of a semiconductor chip or a semiconductor wafer, wherein, in this embodiment, the first circuit component 110 is provided in the form of a printed circuit board (PCB); providing a plurality of first conductive blocks 130 disposed on the first circuit component 110 (S220), wherein the first conductive blocks 130 are made of a conductor, such as metal, and are in direct contact with the first circuit component 110, wherein, in this embodiment, the plurality of first conductive blocks 130 are provided in the form of a plurality of tin blocks; providing an aluminum nitride interposer 120 disposed on the first circuit component 110, wherein the aluminum nitride interposer 120 comprises a plurality of microvias 140, wherein, the microvias 140 each contain a conductor 145 therein, such that one end of the conductor 145 is in contact with a corresponding one of the first conductive blocks 130 (S230), wherein, in this embodiment, aluminum nitride interposer comprises a content of 80˜99.95% aluminum nitride with a thickness of 20 μm-100 μm, wherein the diameter of each of the microvias of the aluminum nitride interposer is 5 μm-100 μm, and the conductor 145 in each of the plurality of microvias 140 is made of copper; providing a plurality of second conductive blocks 150 which is disposed on the aluminum nitride interposer 120 and is in contact with the other ends of the conductors 145 in the plurality of microvias 140 (S240), wherein the second conductive blocks 150 are made of a conductor, such as metal, wherein, in this embodiment, the plurality of second conductive blocks 150 is provided in the form of a plurality of tin blocks; and providing at least a second circuit component 160 disposed on the aluminum nitride interposer 120 and electrically connected to the first circuit component 110 through the first and second conductive blocks 130, 150 and the conductors 145 (S250), wherein, in this embodiment, at least a second circuit component 160 is provided in the form of a CMOS, a DRAM, an ambient light sensor, a power amplifier, a RF and inertia MEMS, or a combination thereof. In a variant embodiment of the present invention, step S250 is followed by the step of covering the three-dimensional integrated circuit comprising an aluminum nitride interposer with a protective layer 170, and the protective layer 170 is made of epoxy resin, for example.

The present invention provides a method of manufacturing a three-dimensional integrated circuit comprising an aluminum nitride interposer with a view to manufacturing a three-dimensional integrated circuit for use with a high-power component. In this regard, aluminum nitride shows excellent properties of insulation and heat dissipation compared to several conventional interposer materials, such as silicon and glass. For a comparison of the properties of three different substrates (silicon, glass, and aluminum nitride), see Table 1 below.

TABLE 1
Comparison of the properties (leakage current, noise and cost) of three
different substrates (silicon, glass and aluminum nitride)

| | Substrates | | |
|---|---|---|---|
| | Silicon | Glass | Aluminum nitride |
| Properties | (semiconductor) | (insulator) | (insulator) |
| Leakage current | Large | Few | Few |
| Noise | Large | Few | Few |
| Thermal | 90 W/m-k | 30-40 W/m-k | 140-220 W/m-k |
| conductivity | | | |
| Cost | High | Low | High |

In this embodiment, microvias are formed in the aluminum nitride interposer by a femtosecond laser. Specifically speaking, the microvias 140 are formed in the aluminum nitride interposer 120 by a titanium-sapphire laser. The titanium-sapphire laser-based drilling process is performed in accordance with the following parameters: a pulse width <100 fs, a frequency of 1,000˜10,000 Hz, a center wavelength of 800 nm, a platform moving speed of 20-200 μm/s, and a laser power of 200-1000 mW. Therefore, microvias 140 with an aspect ratio >5 can be fabricated.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A method of manufacturing a three-dimensional integrated circuit comprising an aluminum nitride interposer, the method comprising the steps of:
providing a first circuit component;
providing a plurality of first conductive blocks on the first circuit component;
providing an aluminum nitride interposer on the first circuit component, wherein the aluminum nitride interposer comprising a plurality of microvias each having therein a conductor with an end in contact with a corresponding one of the first conductive blocks;
providing a plurality of second conductive blocks on the aluminum nitride interposer, wherein the second conductive blocks are in contact with other ends of the conductors in the microvias, respectively; and
providing at least a second circuit component on the aluminum nitride interposer, wherein the at least a second circuit component is electrically connected to the first circuit component through the first and second conductive blocks and the conductors.

2. The method of claim 1, wherein the first circuit component is a PCB.

3. The method of claim 1, wherein the diameter of each microvia is 5-100 μm.

4. The method of claim 1, wherein the at least a second circuit component is at least one of a CMOS, a DRAM, an ambient light sensor, a power amplifier, a RF and inertia MEMS, and a combination thereof.

5. The method of claim 1, wherein the aluminum nitride interposer is of a thickness of 20-100 μm.

6. The method of claim 1, wherein the aluminum nitride interposer comprising a content of 80˜99.95% aluminum nitride.

7. The method of claim 1, wherein the plurality of microvias is formed in the aluminum nitride interposer by performing thereon a femtosecond laser drilling process.

8. The method of claim 7, wherein the drilling process is performed with the femtosecond laser in accordance with parameters, including a center wavelength of 800 nm, a pulse width <100 fs, a laser power of 200˜1,000 mW, and a frequency of 1,000˜10,000 Hz.

9. The method of claim 1, wherein the first and second conductive blocks are tin balls.

10. The method of claim 1, wherein the conductors are made of one of copper, tungsten, silver, tin, and conductive paste.
